(19) United States
(12) Patent Application Publication
(10) Pub. No.: US 2026/0239969 A1
(43) Pub. Date: Aug. 13, 2026

(54) DAM APPLICATION FOR EXPOSED DIE WITH FLAT LID STRUCTURE PACKAGES

(71) Applicant: QUALCOMM Incorporated, San Diego, CA (US)

(72) Inventors: Jaekyu SONG, San Diego, CA (US); Tae Wan KIM, San Diego, CA (US); Rajneesh KUMAR, San Diego, CA (US)

(21) Appl. No.: 19/049,733

(22) Filed: Feb. 10, 2025

(51) Int. Cl. H01L 23/00; H01L 23/31; H01L 23/373; H01L 23/544

(52) U.S. Cl. CPC H10W 40/257; H10W 46/00; H10W 74/117; H10W 46/301; H10W 72/07302; H10W 72/07332; H10W 72/07338; H10W 72/325; H10W 72/353; H10W 72/354; H10W 72/355; H10W 72/381; H10W 90/724; H10W 90/734

(57) ABSTRACT

Disclosed are semiconductor packages. In conventional semiconductor packages with exposed die application, a flat lid is applied on top of the exposed die in which thermal interface material (TIM) is used to increase heat dissipation. But when the lid is pressed, uneven squeeze out of the TIM material can result. By providing a dam to surround the TIM, uneven squeeze out is prevented.

### BACKGROUND OF THE DISCLOSURE

### 1. Field of the Disclosure

This disclosure relates generally to die packages or modules, and more specifically, but not exclusively, to dam application for exposed die with flat lid structure packages and fabrication techniques thereof.

### 2. Description of the Related Art

Integrated circuit (IC) technology has achieved great strides in advancing computing power through miniaturization of active components. In conventional internet of things (IOT) package development, which is an exposed die application, a flat lid is applied on top of the exposed die. To attach the lid, a thermal interface material (TIM) is applied to increase heat dissipation. To make good coverage of TIM or other adhesives, the material needs to be dispensed with pattern control with more precision. Also, uneven squeeze out may cause cosmetic failure concerns at the customer, i.e., detracts from aesthetics. Mechanical and/or thermal integrity issues may also result. Unfortunately, it is difficult to control the bleed out of the dispensed material. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a die on a substrate. An underfill may be between the die and the substrate. The semiconductor package may also comprise a mold on the substrate. The mold may surround side surfaces of the die and the underfill. The semiconductor package may further comprise a thermal interface material (TIM) on an upper surface of the die and on an upper surface of the mold. The semiconductor package may yet comprise a lid on a center portion of the TIM. The lid may be above the die. The semiconductor package may yet further comprise a dam on the mold. The dam may entirely surround the TIM.

A method of fabricating a semiconductor package is disclosed. The method may comprise providing a die on a substrate. An underfill may be between the die and the substrate. The method may also comprise forming a mold on the substrate. The mold may surround side surfaces of the die and the underfill. The method may further comprise forming a thermal interface material (TIM) on an upper surface of the die and on an upper surface of the mold. The method may yet comprise providing a lid on a center portion of the TIM. The lid may be above the die. The method may yet further comprise forming a dam on the mold. The dam may entirely surround the TIM.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIGS. 1A and 1B illustrate cross-sectional and top views of a conventional semiconductor package.

FIG. 2A illustrates a cross-sectional view of a semiconductor package in accordance with one or more aspects of the disclosure.

FIG. 2B-2C illustrate top of examples of semiconductor packages in accordance with one or more aspects of the disclosure.

FIG. 3 illustrates a flow of fabrication steps to fabricate a semiconductor package in accordance with one or more aspects of the disclosure.

FIG. 4-5 illustrate flow charts of example methods of manufacturing a semiconductor package in accordance with at one or more aspects of the disclosure.

FIG. 6 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, the semiconductor package may comprise a die on a substrate. An underfill may be between the die and the substrate. The semiconductor package may also comprise a mold on the substrate. The mold may surround side surfaces of the die and the underfill. The semiconductor package may further comprise a thermal interface material (TIM) on an upper surface of the die and on an upper surface of the mold. The semiconductor package may yet comprise a lid on a center portion of the TIM. The lid may be above the die. The semiconductor package may yet further comprise a dam on the mold. The dam may entirely surround the TIM. As a result, TIM bleed out may be prevented.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

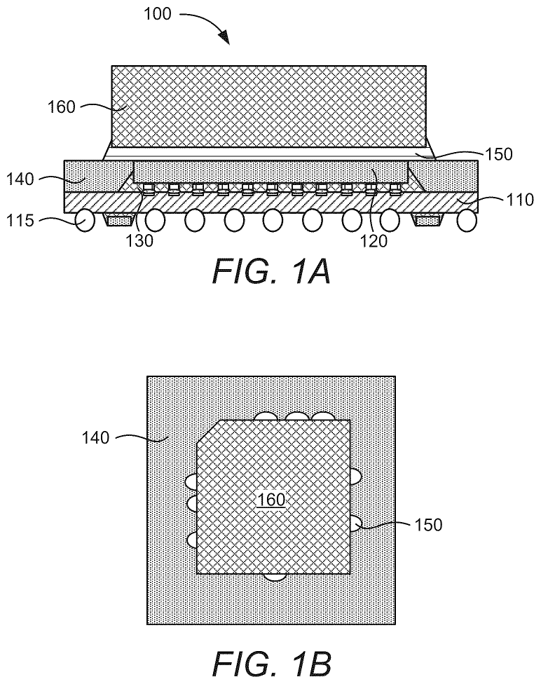

FIG. 1A illustrates a cross-sectional view of a conventional semiconductor package 100. The semiconductor package 100 includes a die 120 on a substrate 110 and a ball grid array (BGA) comprising a plurality of balls 115 below the substrate 110. An underfill 130 is between the die 120 and the substrate 110. A mold 140 is formed on the substrate 110. The mold 140 encapsulates side surfaces of the die 120 and the underfill 130. A thermal interface material (TIM) 150 is formed on an upper surface of the die 120 and on an upper surface of the mold 140. A lid 160 is provided on a center portion of the TIM 150.

As mentioned above, in conventional IOT package development, which is an exposed die application, a flat lid is applied on top of the exposed die. In FIG. 1B, the lid 160 is applied on top of the die 120. To attach the lid, the TIM 150 is applied to increase heat dissipation. FIG. 1B illustrates a top view. As seen, when the lid 160 is attached, uneven squeeze out or bleed out of the TIM 150 can occur. Aesthetically or cosmetically, the squeeze out can be unappealing. This may also present mechanical integrity issues.

Still further, this can make handling of the semiconductor package 100 more difficult. Typically, semiconductor packages are handled-e.g., picked up, moved, etc. using a handler with vacuum power. Unfortunately, when the TIM 150 bleeds out as seen FIG. 1B, vacuum handling may be compromised. Unfortunately, it is difficult to control the bleed out of the TIM 150 when the lid 160 is attached.

To address these and other issues of the conventional semiconductor package, it is proposed to create a dam structure around the flat lid attached position. The dam can act as a mechanical barrier to prevent material bleed-out. Also, keep out zone (KOZ) can be maintained by the dam. Also, the dam material can be dispensed with a specific pattern. The dispensed pattern can be used a fiducial (e.g., alignment) mark.

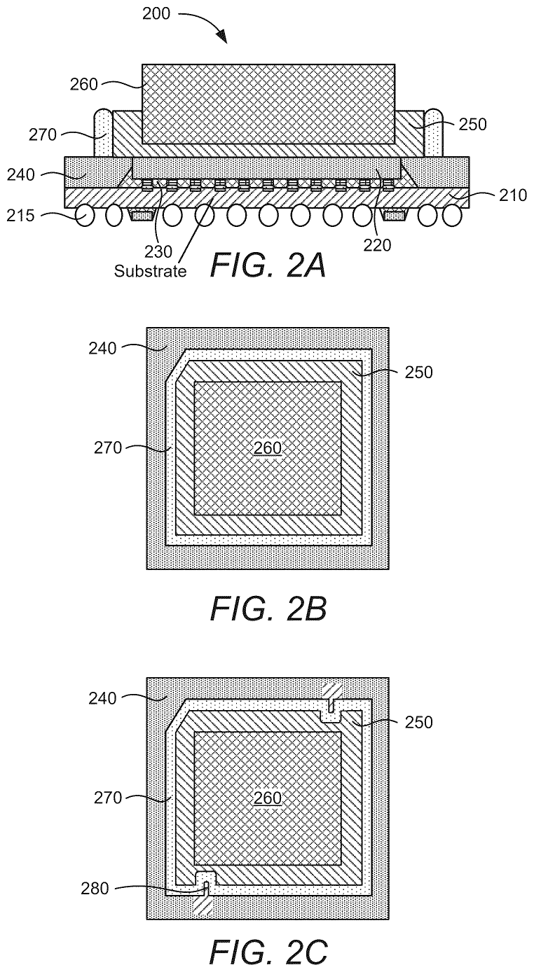

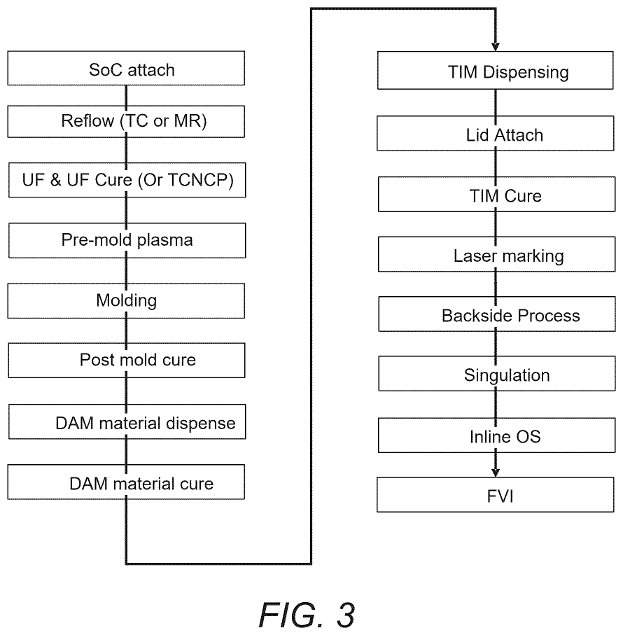

FIG. 2A illustrates a cross-sectional view of a semiconductor package 200 in accordance with one or more aspects. The semiconductor package 200 may include a substrate 210, a ball grid array (BGA) comprising a plurality of balls 215 below the substrate 210, and a die 220 may be provided on the substrate 210. An underfill 230 may be formed between the die 220 and the substrate 210. In an aspect, the underfill 230 may be a capillary underfill, e.g., formed from epoxy resin. The capillary underfill may also include a hardener, a filler (e.g., SiO₂ filler), and additives including flexible and adhesion promoter.

A mold 240 may be formed on the substrate 210 and may encapsulate side surfaces of the die 220 and the underfill 230. In an aspect, the mold 240 may be from an epoxy molding compound (EMC). The composition of the EMC may be in tablet form or in powder form. At room temperature, the EMC may be solid. But at high temperatures (e.g., higher than 100° C.), it may be liquid. A thermal interface material (TIM) 250 may be formed on an upper surface of the die 220 and on an upper surface of the mold 240. In an aspect, the TIM 250 may be an adhesive type TIM. The adhesive may be formed from a silicone-based material with hardener and may include ceramic high thermal fillers (e.g., alumina (Al₂O₃), boron nitride (BN), etc.) and/or high thermal metal fillers (e.g., silver (Ag), copper (Cu), etc.). A lid 260 may be provided on a center portion of the TIM 250. The lid 260 may be provided above the die 220.

The semiconductor package 200 may include a dam 270 formed on the mold 240. As seen in FIG. 2B, which illustrates a top view of one example of the semiconductor package 200, the dam 270 may entirely surround the TIM 250. As seen in FIGS. 2A and 2B, the dam 270 may act as a physical barrier to contain the TIM 250. That is, when the lid 260 is attached to the TIM 250, the TIM 250 is prevented from flowing outside the boundary defined by the dam 270.

The dam 270 may be shaped to generally correspond to the shape of the lid 260. For example, if the lid 260 is square shaped, rectangular shaped, etc., the dam 270 may also be square shaped, rectangular shaped, etc. Alternatively or in addition thereto, the dam 270 may be shaped such that a distance from edges of the lid 260 to the dam 270 is substantially a constant.

FIG. 2C illustrates a top view of another example of the semiconductor package 200. One difference between FIGS. 2B and 2C is that one or more alignment marks 280 may be incorporated into the dam 270. In this instance, the alignment marks 280 are ‘U’ shaped. However, this is merely an example, and the alignment marks 280 may take on any shape. The alignment marks 280 can help in the placement of the lids 260. For example, the lids 260 may be placed in a fixed relationship with the alignment marks 280. Also, when multiple semiconductor packages 200 are involved, the alignment marks 280 may help is spacing out the semiconductor packages 200 by an automated handler.

Since the dam 270 may act to contain the TIM 250, the dam 270 may have higher viscosity than the TIM 250. For example, the dam 270 may be formed from materials based on any combination of epoxy, silicone, acrylic, imide, etc. In an aspect, the dam support 275 may be more rigid or stiffer than the underfill 230. That is, the material for the dam 270 may have higher viscosity to form the dam shape. The dam 270, in an aspect, may be formed outside the die or lid area to prevent the material for the TIM 250 from being squeezed out.

Also since the dam 270 may act to contain the TIM 250, more TIM 250 may be dispensed. As seen in FIG. 2A, enough material for the TIM 250 may be dispensed such that when the lid 260 is attached, the TIM 250 may be on the lower surface of the lid 260 and on at least a portion of the side surface of the lid 260. That is, an outer portion of the TIM 250 may completely surround the lid 260. The height of the outer portion of the TIM 250 may be above a lower surface of the lid 260 and below an upper surface of the lid 260. This means that relative to the conventional semiconductor package 100, in the proposed semiconductor package 200, a greater amount of the TIM 250 can be in physical contact with the lid 260. As a result, thermal performance can be improved.

A height of the dam 270 may be greater than or equal to the height of the outer portion of the TIM 250. That is, the amount of material for the TIM 250 should be such that the TIM 250 does not overflow the dam 270.

Note that in an aspect, the upper surfaces of the die 220 and the mold 240 may be planar, e.g., at a same height. The TIM 250 may cover an entirety of the upper surface of the die 220 and cover at least a portion of the upper surface of the mold 240.

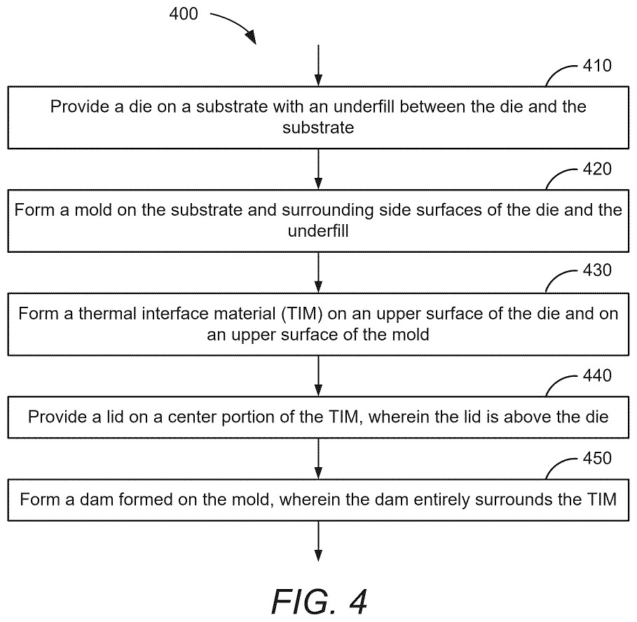

FIG. 3 illustrates a flow of fabrication steps to fabricate a semiconductor package in accordance with one or more aspects of the disclosure.

It should be noted not all steps are required. It should also be noted that unless otherwise specifically indicated, the steps need not be performed in the order shown.

Majority of the steps shown may be referred to as already being known. However, for the purposes of this disclosure, the steps of dispensing the dam material and curing the dam material may be particularly relevant. In these steps, the material for the dam 270 may be dispensed on the mold 240, and the dispensed material for the dam 270 may be cured. Thereafter, material for the TIM 250 may be dispensed (e.g., with the aid of the alignment marks 280) on the die 220, and the lid 260 may be placed on the TIM 250. Thereafter, the material for the TIM 250 may be cured.

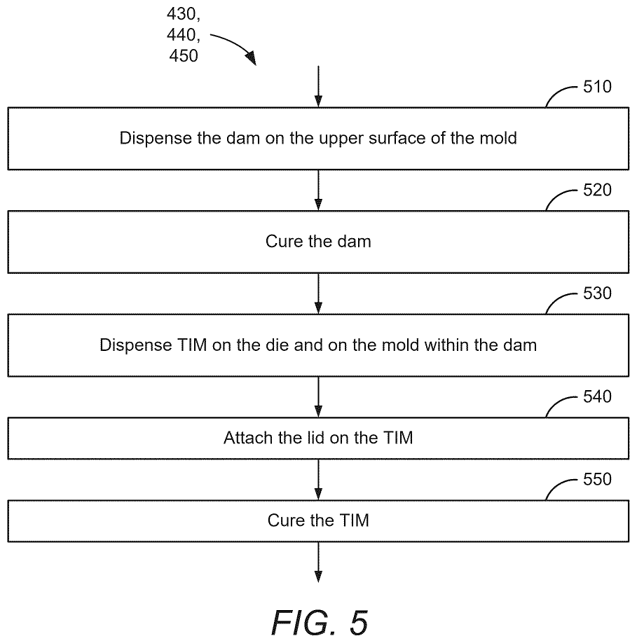

FIG. 4 illustrates a flow chart of an example method 400 of fabricating a semiconductor package, such as the semiconductor packages 200, in accordance with one or more aspects of the disclosure.

In block 410, a die 220 may be provided on a substrate 210. An underfill 230 may be between the die 220 and the substrate 210.

In block 420, a mold 240 may be formed on the substrate 210. The mold 240 may encapsulate side surfaces of the die 220 and the underfill 230.

In block 430, a thermal interface material (TIM) 250 may be formed on an upper surface of the die 220 and on an upper surface of the mold 240.

In block 440, a lid 260 may be provided on a center portion of the TIM 250. The lid 260 may be above the die 220.

In block 450, a dam 270 may be formed on the mold 240. The dam 270 may entirely surround the TIM 250.

FIG. 5 illustrates an example of a process to implement block 430 of forming the mold 240, block 440 of providing the lid 260, and block 450 of forming the dam. In block 510, the dam 270 may be dispensed on the upper surface of the mold 240.

In block 520, the dam 270 may be cured.

In block 530, the TIM 250 may be dispensed on the die 220 and on the mold 240 within the dam 270.

In block 540, the lid 260 may be attached on the TIM 250.

In block 550, the TIM 250 may be cured.

The following should be noted regarding the flow indicated in FIG. 4-5. Unless otherwise indicated, the flow of blocks do not necessarily limit the ordering in which the blocks may be performed. In other words, the blocks may be performed in any order that is logical.

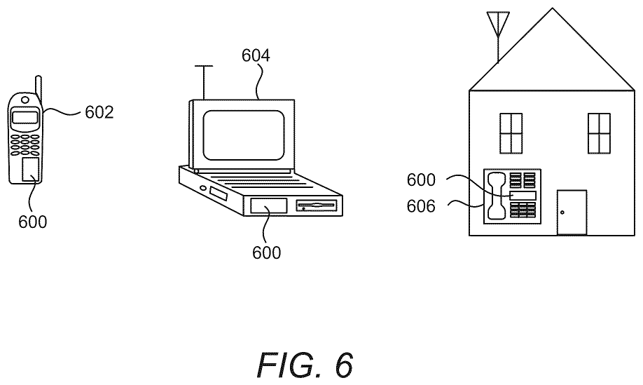

FIG. 6 illustrates various electronic devices 600 that may be integrated with any of the aforementioned semiconductor packages in accordance with various aspects of the disclosure. For example, a mobile phone device 602, a laptop computer device 604, and a fixed location terminal device 606 may each be considered generally user equipment (UE) and may include one or more semiconductor packages (e.g., semiconductor package 200) as described herein. The devices 602, 604, 606 illustrated in FIG. 6 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: A semiconductor package, comprising: a die on a substrate with an underfill between the die and the substrate; a mold on the substrate and encapsulating side surfaces of the die and the underfill; a thermal interface material (TIM) on an upper surface of the die and on an upper surface of the mold; a lid on a center portion of the TIM, wherein the lid is above the die; and a dam on the mold, wherein the dam entirely surrounds the TIM.
Clause 2: The semiconductor package of clause 1, wherein one or more alignment marks are formed by the dam.
Clause 3: The semiconductor package of any of clauses 1-2, wherein the dam is formed from a material based on any one or more of epoxy, silicone, acrylic, and imide.
Clause 4: The semiconductor package of any of clauses 1-3, wherein the dam has a higher viscosity than the TIM.
Clause 5: The semiconductor package of any of clauses 1-4, wherein an outer portion of the TIM is between the lid and the dam.
Clause 6: The semiconductor package of clause 5, wherein the outer portion of the TIM completely surrounds the lid, and is at a height that is above a lower surface of the lid and below an upper surface of the lid.
Clause 7: The semiconductor package of any of clauses 5-6, where a height of the dam is greater than or equal to a height of the outer portion of the TIM.
Clause 8: The semiconductor package of any of clauses 1-7, wherein the TIM covers an entirety of the upper surface of the die and covers a portion of the upper surface of the mold.
Clause 9: The semiconductor package of any of clauses 1-8, wherein the upper surfaces of the die and the mold are planar.
Clause 10: The semiconductor package of any of clauses 1-9, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 11: A method of fabricating a semiconductor package, the method comprising: providing a die on a substrate with an underfill between the die and the substrate; forming a mold on the substrate and encapsulating side surfaces of the die and the underfill; forming a thermal interface material (TIM) on an upper surface of the die and on an upper surface of the mold; providing a lid on a center portion of the TIM, wherein the lid is above the die; and forming a dam on the mold, wherein the dam entirely surrounds the TIM.
Clause 12: The semiconductor package of clause 11, wherein one or more alignment marks are formed by the dam.
Clause 13: The semiconductor package of any of clauses 11-12, wherein the dam is formed from a material based on any one or more of epoxy, silicone, acrylic, and imide.
Clause 14: The semiconductor package of any of clauses 11-13, wherein the dam has a higher viscosity than the TIM.
Clause 15: The semiconductor package of any of clauses 11-14, wherein an outer portion of the TIM is between the lid and the dam.
Clause 16: The semiconductor package of clause 15, wherein the outer portion of the TIM completely surrounds the lid, and is at a height that is above a lower surface of the lid and below an upper surface of the lid.
Clause 17: The semiconductor package of any of clauses 15-16, where a height of the dam is greater than or equal to a height of the outer portion of the TIM.
Clause 18: The semiconductor package of any of clauses 11-17, wherein the TIM covers an entirety of the upper surface of the die and covers a portion of the upper surface of the mold.
Clause 19: The semiconductor package of any of clauses 11-18, wherein the upper surfaces of the die and the mold are planar.
Clause 20: The semiconductor package of any of clauses 11-19, wherein forming the TIM, providing the lid, and forming the dam comprises: dispensing the dam on the upper surface of the mold; curing the dam; dispensing the TIM on the die and on the mold within the dam; attaching the lid on the TIM; and curing the TIM.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that-although a dependent claim can refer in the claims to a specific combination with one or one or more claims-other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a die on a substrate with an underfill between the die and the substrate;
a mold on the substrate and encapsulating side surfaces of the die and the underfill;
a thermal interface material (TIM) on an upper surface of the die and on an upper surface of the mold;
a lid on a center portion of the TIM, wherein the lid is above the die; and
a dam on the mold, wherein the dam entirely surrounds the TIM.

2. The semiconductor package of claim 1, wherein one or more alignment marks are formed by the dam.

3. The semiconductor package of claim 1, wherein the dam is formed from a material based on any one or more of epoxy, silicone, acrylic, and imide.

4. The semiconductor package of claim 1, wherein the dam has a higher viscosity than the TIM.

5. The semiconductor package of claim 1, wherein an outer portion of the TIM is between the lid and the dam.

6. The semiconductor package of claim 5, wherein the outer portion of the TIM completely surrounds the lid, and is at a height that is above a lower surface of the lid and below an upper surface of the lid.

7. The semiconductor package of claim 5, where a height of the dam is greater than or equal to a height of the outer portion of the TIM.

8. The semiconductor package of claim 1, wherein the TIM covers an entirety of the upper surface of the die and covers a portion of the upper surface of the mold.

9. The semiconductor package of claim 1, wherein the upper surfaces of the die and the mold are planar.

10. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

11. A method of fabricating a semiconductor package, the method comprising:
providing a die on a substrate with an underfill between the die and the substrate;
forming a mold on the substrate and encapsulating side surfaces of the die and the underfill;
forming a thermal interface material (TIM) on an upper surface of the die and on an upper surface of the mold;
providing a lid on a center portion of the TIM, wherein the lid is above the die; and
forming a dam on the mold, wherein the dam entirely surrounds the TIM.

12. The method of claim 11, wherein one or more alignment marks are formed by the dam.

13. The method of claim 11, wherein the dam is formed from a material based on any one or more of epoxy, silicone, acrylic, and imide.

14. The method of claim 11, wherein the dam has a higher viscosity than the TIM.

15. The method of claim 11, wherein an outer portion of the TIM is between the lid and the dam.

16. The method of claim 15, wherein the outer portion of the TIM completely surrounds the lid, and is at a height that is above a lower surface of the lid and below an upper surface of the lid.

17. The method of claim 15, where a height of the dam is greater than or equal to a height of the outer portion of the TIM.

18. The method of claim 11, wherein the TIM covers an entirety of the upper surface of the die and covers a portion of the upper surface of the mold.

19. The method of claim 11, wherein the upper surfaces of the die and the mold are planar.

20. The method of claim 11, wherein forming the TIM, providing the lid, and forming the dam comprises:
dispensing the dam on the upper surface of the mold;
curing the dam;
dispensing the TIM on the die and on the mold within the dam;
attaching the lid on the TIM; and
curing the TIM.
